(19) United States
(12) Patent Application Publication
(10) Pub. No.: US 2013/0164882 A1
(43) Pub. Date: Jun. 27, 2013

(54) TRANSPARENT CONDUCTING LAYER FOR SOLAR CELL APPLICATIONS

(71) Applicants: Ali Afzali-Ardakani, Ossining, NY (US); Ageeth A. Bol, Yorktown Heights, NY (US); Mostafa M. EI-Ashry, Elmsford, NY (US); Amal Kasry, White Plains, NY (US); Ahmed Maarouf, Mohegan Lake, NY (US); Glenn J. Martyna, Croton on Hudson, NY (US); Dennis M. Newns, Yorktown Heights, NY (US); Razvan Nistor, New york, NY (US); George S. Tulevski, White Plains, NY (US)

(72) Inventors: Ali Afzali-Ardakani, Ossining, NY (US); Ageeth A. Bol, Yorktown Heights, NY (US); Mostafa M. EI-Ashry, Elmsford, NY (US); Amal Kasry, White Plains, NY (US); Ahmed Maarouf, Mohegan Lake, NY (US); Glenn J. Martyna, Croton on Hudson, NY (US); Dennis M. Newns, Yorktown Heights, NY (US); Razvan Nistor, New york, NY (US); George S. Tulevski, White Plains, NY (US)

(73) Assignee: International Business Machines Corporation, Armonk, NY (US)

(21) Appl. No.: 13/337,002

(22) Filed: Dec. 23, 2011

(51) Int. Cl. H01L 31/0352; H01L 31/0224

(52) U.S. Cl. 438/87; 438/98; 257/E31.037; 257/E31.125

(57) ABSTRACT

Disclosed is a method which includes forming a bottom metallic electrode on an insulating substrate; forming a semiconductor junction on the metallic electrode; forming a transparent conducting overlayer in contact with the semiconductor junction; and forming a metallic layer in contact with the transparent conducting overlayer, wherein the metallic layer is formed by a plating process. The plating process may be an electroplating process or an electroless plating process. The transparent conducting overlayer may be carbon nanotubes or graphene. The semiconductor junction may be a p-i-n semiconductor junction, a p-n semiconductor junction, an n-p semiconductor junction or an n-i-p semiconductor junction.

### BACKGROUND

The present invention relates to structures having a transparent conducting overlayer and, more particularly, relates to the formation of structures having a transparent conducting overlayer and metallic layer for solar cell applications and display applications.

Solar cells may be manufactured using a p-i-n type of semiconductor junction. The semiconductor material making up the p-i-n semiconductor junction may be amorphous silicon to reduce cost. An example of one such solar cell 10 is shown in FIG. 1 having a p-i-n semiconductor junction 12 made up of an n-doped layer 14, a p-doped layer 16 and an undoped insulator layer 18. Typically, solar radiation 20 enters through the p-doped layer 16 of the p-i-n semiconductor junction 12. The electron current from n-doped layer 14 is collected via a metal conductor 22 with relatively low work function. The hole current from the p-doped layer 16 is collected via a transparent conducting overlayer (TCO) 24 with a relatively high work function. The TCO 24 is necessary because of the poor electrical conductivity of the p-doped layer 16 and enables the solar cell 10 to have an acceptably low output impedance, such as is possible with a top layer conductance of 10 Ohms/square, along with a desired optical transparency of greater than about 90%. The solar cell may be built on a rigid or flexible insulating material (not shown).

The TCO 24 may be a relatively thick film (50-100 nm) of indium tin oxide (ITO) or aluminum-doped zinc oxide (ZnO), the latter with the advantage of avoiding the rare element indium. However, these oxide film transparent conducting overlayers require expensive deposition techniques and are brittle, so they cannot be used in flexible solar cells such as may be the optimal type for low-cost mass production.

### BRIEF SUMMARY

The various advantages and purposes of the exemplary embodiments as described above and hereafter are achieved by providing, according to a first aspect of the exemplary embodiments, a method including forming a bottom metallic electrode; forming a semiconductor junction on the metallic electrode; forming a transparent conducting overlayer in contact with the semiconductor junction; and forming a metallic layer in contact with the transparent conducting overlayer, wherein the metallic layer is formed by a plating process.

According to a second aspect of the exemplary embodiments, there is provided a method including forming a bottom metallic electrode; forming a semiconductor junction on the metallic electrode, the semiconductor junction being in direct contact with the bottom metallic electrode; forming a transparent conducting overlayer over and in direct contact with the semiconductor junction; and forming a metallic layer over and in direct contact with the transparent conducting overlayer, wherein the metallic layer is formed by a plating process.

According to a third aspect of the exemplary embodiments, there is provided a method including forming a bottom metallic electrode; forming a semiconductor junction on the metallic electrode, the semiconductor junction being in direct contact with the bottom metallic electrode; forming a metallic layer over and in direct contact with the semiconductor junction, wherein the metallic layer is formed by a plating process; and forming a transparent conducting overlayer over and in direct contact with the metallic layer.

### BRIEF DESCRIPTION OF SEVERAL VIEWS OF THE DRAWINGS

The features of the exemplary embodiments believed to be novel and the elements characteristic of the exemplary embodiments are set forth with particularity in the appended claims. The Figures are for illustration purposes only and are not drawn to scale. The exemplary embodiments, both as to organization and method of operation, may best be understood by reference to the detailed description which follows taken in conjunction with the accompanying drawings in which:

FIG. 1 is a schematic cross-sectional view of a conventional solar cell.

FIG. 2 is a schematic cross-sectional view of an exemplary embodiment of a solar cell.

FIG. 3 is a schematic cross-sectional view of a second exemplary embodiment of a solar cell.

FIG. 4 is a plan view of a bus bar and fingers configuration of a metallic layer for the exemplary embodiments.

FIG. 5 is a process flow chart for forming the exemplary embodiments.

FIG. 6 is a schematic cross-sectional view of a third exemplary embodiment of a solar cell.

FIG. 7 is a schematic cross-sectional view of a fourth exemplary embodiment of a solar cell.

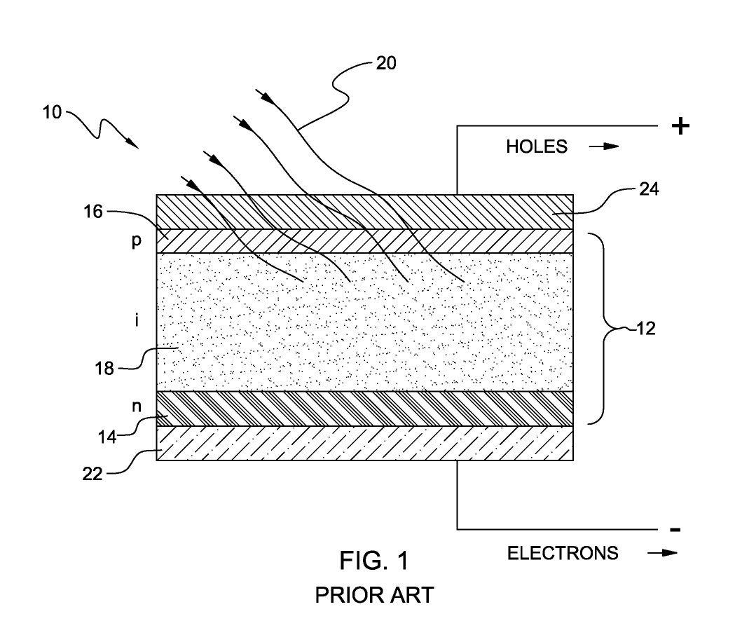

### DETAILED DESCRIPTION

Carbon nanotubes have been proposed as an alternative material for the transparent conducting overlayers in solar cells. The carbon nanotubes (CNT) may be in the form of a mat of CNT. While very high transparencies are achievable with CNT, the electrical resistivity of 80% transparent CNT mat films is still unacceptably high, in the 60-250 Ohms/square range, for them to be used as one-for-one replacements for Indium Tin Oxide (ITO) or Al-doped zinc oxide (ZnO) TCO films.

A proposed solution is to form a metallic layer over the CNT mat layer. In a preferred embodiment, the metallic layer is a pattern of busbars and fingers in a highly-conducting metal such as copper over the CNT mat layer. The resulting composite two-component overlayer microstructure forms a transparent conducting overlayer with both a high optical transparency and a low electrical resistance which can functionally replace transparent conducting overlayer oxide layers.

Graphene, an allotrope of carbon, may also be used in place of the CNT mat layer. Graphene typically refers to a single planar sheet of covalently bonded carbon atoms. In essence, graphene is an isolated atomic plane of graphite. Graphene is believed to be formed of a plane of carbon atoms that are sp²-bonded carbon to form a regular hexagonal lattice with an aromatic structure. The thickness of graphene is one atomic layer of carbon. That is, graphene does not form a three-dimensional crystal. However, multiple sheets of graphene may be stacked. A typical graphene “layer” may include a single sheet or multiple sheets of graphene.

In a most preferred embodiment, the metallic layer is formed by a plating process such as by electroplating or electroless plating.

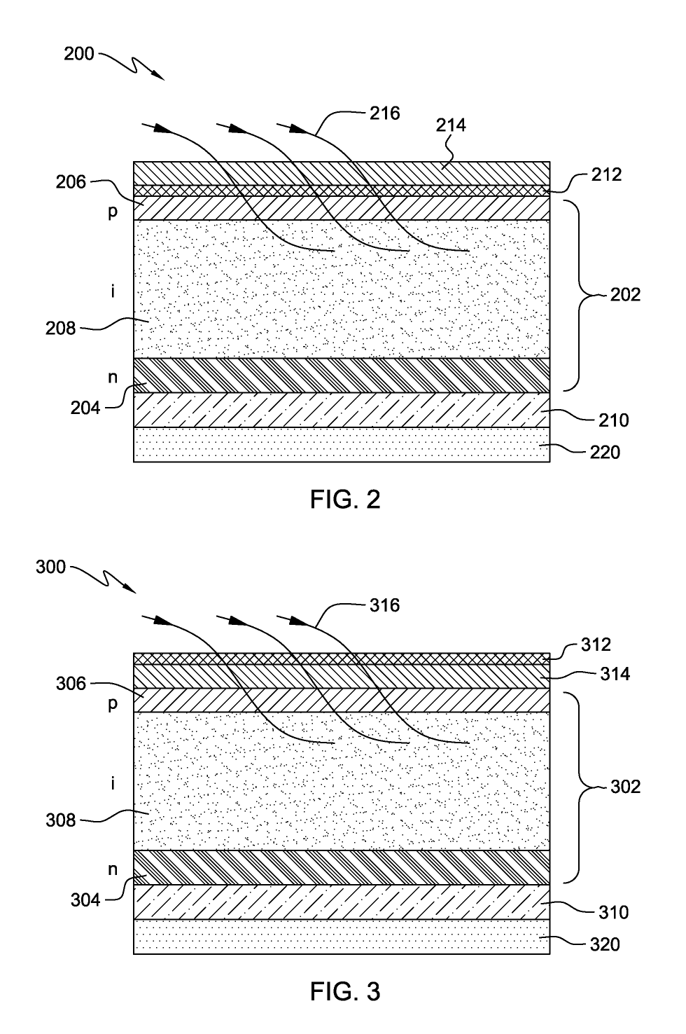

Referring now to FIG. 2, there is shown a first exemplary embodiment of the present invention. The structure 200 includes a p-i-n semiconductor junction 202 with an n-doped layer 204, a p-doped layer 206 and an undoped insulator layer 208. In contact with the n-doped layer 204 is a metallic layer or electrode 210. In contact with the p-doped layer 206 is a TCO 212. In contact with TCO 212 is a metallic layer 214. When the structure 200 is utilized for solar cell applications, the metallic layer 214 should have an open structure to allow solar radiation 216 to contact the TCO 212 and the underlying p-i-n semiconductor junction 202. The structure 200 may also have a rigid or flexible substrate 220, preferably insulating, when the structure is used as a solar cell. The p-i-n semiconductor junction 202 may be made from any of the semiconductor materials commonly used for solar cell applications with amorphous silicon being preferred because of low cost.

The TCO 212 may include a CNT mat or graphene. CNT mats may be formed by the following process steps. In one process, CNT mats may be formed by the vacuum filtration technique. A purified, diluted nanotube solution of CNTs dispersed in water and a sufactant is filtered through cellulose ester membranes (MF-Millipore Membrane, mixed cellulose esters, Hydrophilic, 0.1 μm, 25 mm) to form a uniform nanotube film. The process involves the pretreatment of membranes with a small amount of DI water and subsequent filtration of different volumes of nanotube solution to achieve varying thickness of nanotube film. The filtration speed is kept as low as possible to achieve films with high degree of uniformity. Filtered nanotube film material on membrane is then allowed to set for 15-20 minutes. 50 mL of water is slowly passed through the film to wash off the surfactant. Post wash, the film is left to dry in air for 15 minutes. The target glass slide on which the nanotube film is to be transferred is made wet with single drop of DI water. The nanotube film side of the membrane is made in contact with the wet glass and a small pressure is applied to make them stick together. The membrane is then slowly dissolved in acetone, leaving nanotube film on the glass slide. The nanotube film is kept in acetone for 30 minutes for complete removal of residual filter paper. The film is transferred to the semiconductor by scooping the film suspended in solution using the semiconductor. CNT films may also be produced by spin-coating, dip-coating, doctor blading or spray coating.

Graphene for the TCO may be made by the following process steps. Graphene transparent electrodes may be made from the growth of graphene by chemical vapor deposition (CVD) on copper foils. A carbon source (ethylene, ethanol etc.) is flowed into a furnace with copper foil heated to greater than 800° C. A single layer of graphene is grown on the copper foil. The graphene is then transferred to the desired substrate via delamination or roll-to-roll transfer. Graphene may also be formed by thermal decomposition, exfoliation from graphite or assembly of graphene films from solution. It should be understood that forming the graphene on structure 200 includes forming the graphene directly on structure 200 as well as forming the graphene separately and then transferring the graphene to structure 200.

The metal busbar architecture can be formed on graphene regardless of the graphene's origin, whether it be CVD, thermal decomposition, exfoliation from graphite or assembly of graphene films from solution.

The foregoing description of the CNT mats and graphene are for purposes of illustration and not limitation. The CNT mats and graphene may be formed on the structure 200 by any other method known now or in the future.

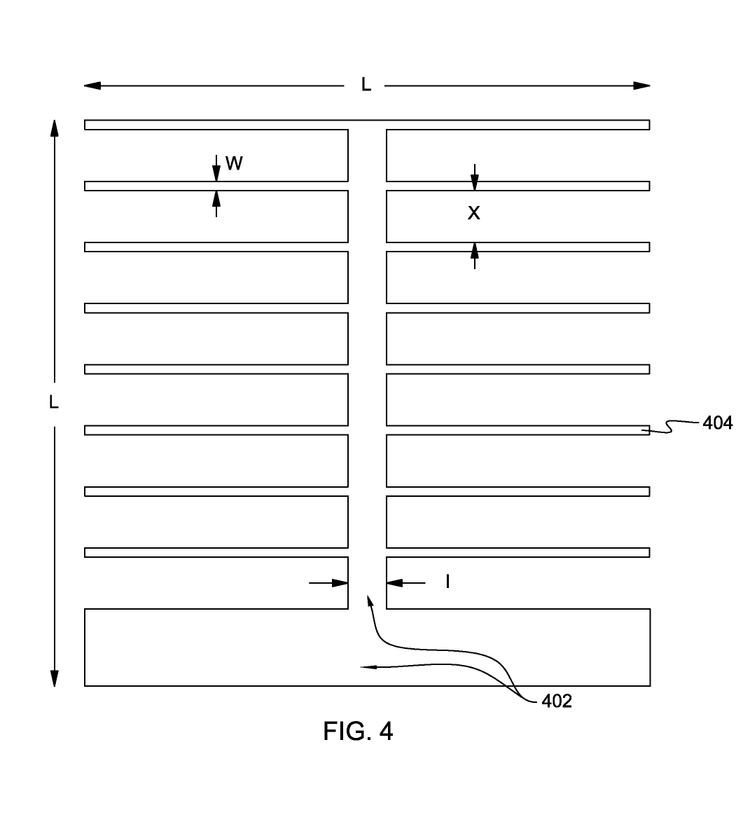

A preferred embodiment is for metallic layer 214 to be in the form of busbars and fingers as shown in FIG. 4. Metallic layer 214 forms an overlayer on top of the TCO 212 and performs the task of collecting current from the TCO 212, which itself collects current from the underlying p-i-n semiconductor junction 202. FIG. 4 shows a busbar 402 plus two sets of fingers 404 dividing up a square space of the surface for the purpose of current collection. In order to maintain transparency, the metalized area will typically take up about 8% of the surface area of the solar cell. Exemplary dimensions for the busbar 402 and fingers 404 are:

w=60 micrometers

x=0.15 centimeters

L=3 centimeters

I=0.12 centimeters.

It should be understood that the above dimensions are for purposes of illustration only and not limitation.

The metallic layer 214 should be formed by a plating process including electroplating or electroless plating. The use of a plating process is advantageous in that it is a low cost, solution based process and can be performed at room temperature. In the case of electroless plating, a plating seed (typically palladium-based seeds) are patterned on the carbon films surface. The patterning can be done via stamping of an organic layer that is charged to bind to the seeds or by directly stamping the seeds themselves. Once the palladium particles are patterned on the carbon film, the film is dipped in an electroless metal (for example, copper) bath where the patterned areas are metalized to form metallic layer 214. Electroplating may be performed by patterning the surface of the carbon film with a resist layer that only leaves areas of the carbon film exposed where metal is desired. The sample can then be placed in an electroplating bath where a bias is applied to the carbon film, resulting in metallization in the exposed areas of the film to form metallic layer 214.

Referring now to FIG. 3, there is shown another exemplary embodiment of the present invention. Structure 300 includes a p-i-n semiconductor junction 302 having an n-doped layer 304, a p-doped layer 306 and an undoped insulating layer 308. A metallic layer or electrode 310 contacts n-doped layer 304. The structure 300 may include a rigid or flexible substrate 320, which preferably is an insulating substrate. In this embodiment, the positions of the TCO 312 and metallic layer 314 are reversed compared to the structure 200 shown in FIG. 3. That is, metallic layer 314 is in contact with p-doped layer 306 while TCO 312 is on top of structure 300 and in contact with metallic layer 314. The TCO 312 may include a CNT mat or graphene as described previously. The p-i-n semiconductor junction 302 may be made from any of the semiconductor materials commonly used for solar cell applications with amorphous silicon being preferred because of low cost. When used as a solar cell, solar radiation 316 may contact the structure 300 to generate an electric current.

It is preferred that the metallic layer 314 be in the form of busbars and fingers as shown in FIG. 4 and as described previously.

The metallic layer 314 should be formed from a plating process including electroplating and electroless plating as described previously.

The structure 300 has several advantages over the structure 200. The metallic layer 314 will be more stable due to the good contact with the p-i-n semiconductor junction 302. The porosity of the TCO 312 would not be an issue since the TCO is on top and the metallic layer 314 will not be penetrating through the TCO 312.

While the exemplary embodiments shown in FIGS. 2 and 3 are illustrated using a p-i-n semiconductor junction, it should be understood that an n-i-p semiconductor junction, an n-p semiconductor junction or a p-n semiconductor junction may also be used for the exemplary embodiments.

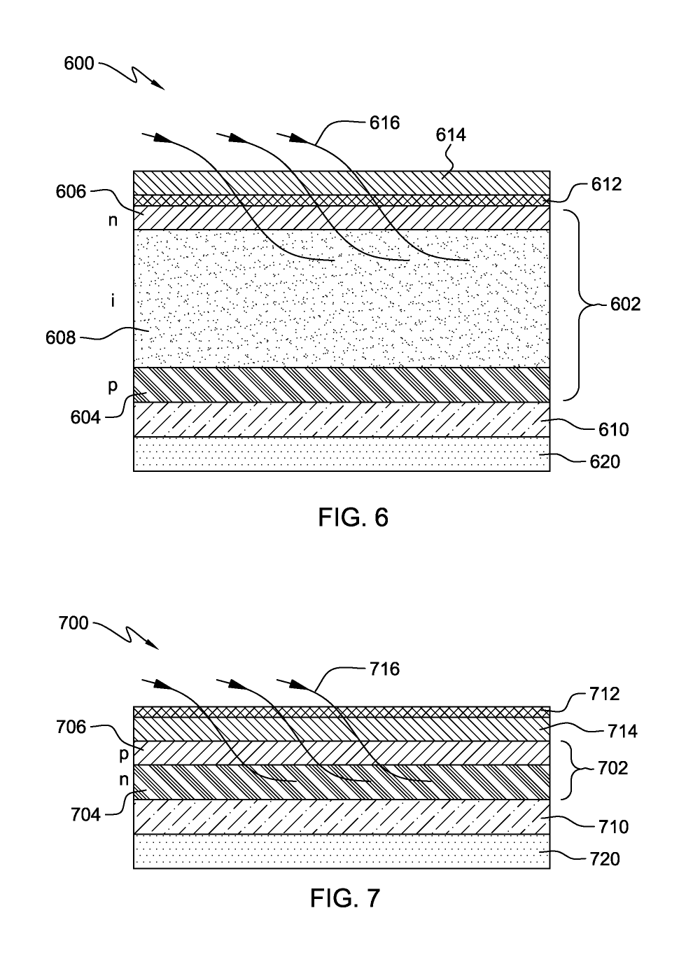

Referring to FIG. 6, there is shown the exemplary embodiment of FIG. 2 using an n-i-p semiconductor junction. The structure 600 includes an n-i-p semiconductor junction 602 with a p-doped layer 604, an n-doped layer 606 and an undoped insulator layer 608. In contact with the p-doped layer 604 is a metallic layer or electrode 610. In contact with the n-doped layer 606 is a TCO 612 which may be a CNT mat or graphene as described previously. In contact with TCO 612 is a metallic layer 614. When the structure 600 is utilized for solar cell applications, the metallic layer 614 should have an open structure to allow solar radiation 616 to contact the TCO 612 and the underlying n-i-p semiconductor junction 602. The structure 600 may also have a rigid or flexible substrate 620, preferably insulating, when the structure is used as a solar cell. The n-i-p semiconductor junction 602 may be made from any of the semiconductor materials commonly used for solar cell applications with amorphous silicon being preferred because of low cost.

The exemplary embodiment of FIG. 2 may also be fabricated using an n-p semiconductor junction or a p-n semiconductor junction.

Referring to FIG. 7, there is shown the exemplary embodiment of FIG. 3 using a p-n semiconductor junction. Structure 700 includes a p-n semiconductor junction 702 having an n-doped layer 704 and a p-doped layer 706. A metallic layer or electrode 710 contacts n-doped layer 704. The structure 700 may include a rigid or flexible substrate 720, which preferably is an insulating substrate. Metallic layer 714 is in contact with p-doped layer 706 while TCO 712 is on top of structure 700 and in contact with metallic layer 714. The TCO 712 may include a CNT mat or graphene as described previously. The p-n semiconductor junction 702 may be made from any of the semiconductor materials commonly used for solar cell applications with amorphous silicon being preferred because of low cost. When used as a solar cell, solar radiation 716 may contact the structure 700 to generate an electric current.

The exemplary embodiment of FIG. 3 may also be fabricated using an n-p or an n-i-p semiconductor junction.

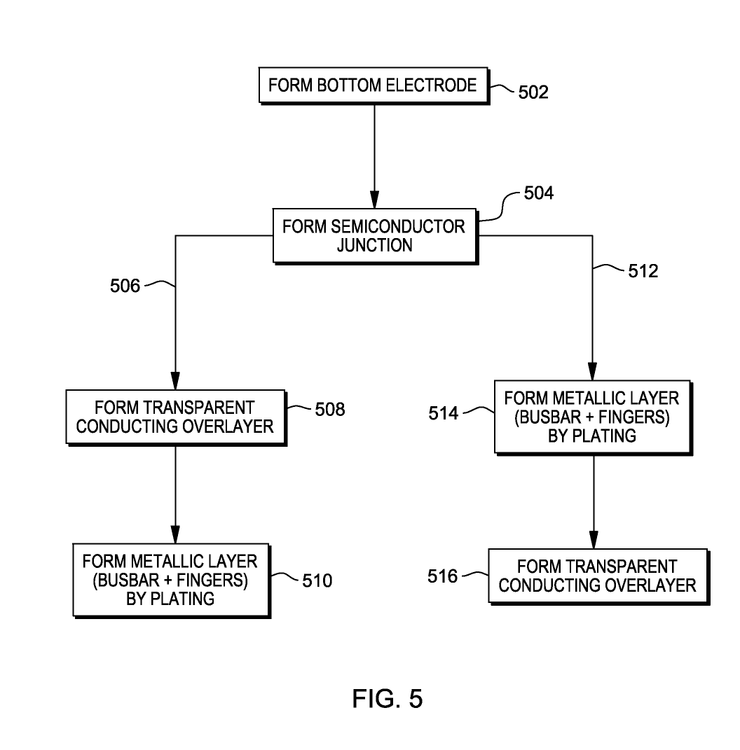

The processes for forming the embodiments of the invention are described with respect to FIG. 5. A bottom electrode (for example, 210 in FIG. 2; 310 in FIG. 3; 610 in FIG. 6; 710 in FIG. 7) is first conventionally formed as indicated by box 502. For solar applications, it may be desirable to form this bottom electrode on a rigid or flexible substrate (for example, 220 in FIG. 2; 320 in FIG. 3; 620 in FIG. 6; 720 in FIG. 7) for handling. A flexible substrate may be more desirable for present day solar cells because of its ease of handling and low cost.

Thereafter, a semiconductor junction (for example, 202 in FIG. 2; 302 in FIG. 3, 602 in FIG. 6, 702 in FIG. 7) is conventionally formed on the bottom electrode as indicated by box 504.

At this point in the process flow, the process could diverge and take a left branch or right branch. The left branch describes the process flow for the structure 200 shown in FIG. 2 and structure 600 shown in FIG. 6 while the right branch describes the process flow for the structure 300 shown in FIG. 3 and the structure 700 in FIG. 7.

With respect to the left branch 506 of the process flow, the transparent conducting overlayer (for example, 212 in FIG. 2; 612 in FIG. 6) is formed as described previously on the semiconductor junction (for example, 202 in FIG. 2; 602 in FIG. 6) as indicated by box 508.

Thereafter, the metallic layer (for example, 214 in FIG. 2; 614 in FIG. 6), such as the busbar plus fingers shown in FIG. 4, is formed by a plating process as indicated by box 510.

With respect to the right branch 512 of the process flow, the metallic layer (for example, 314 in FIG. 3; 714 in FIG. 7), such as the busbar plus fingers shown in FIG. 4, is formed by a plating process on the semiconductor junction (for example, 302 in FIG. 3, 702 in FIG. 7) as indicated by box 514.

Thereafter, the transparent conducting overlayer (for example, 312 in FIG. 3, 712 in FIG. 7) is formed as described previously on the metallic layer (for example, 314 in FIG. 3, 714 in FIG. 7) as indicated by box 516.

While the exemplary embodiments have been primarily directed to solar cell applications, the exemplary embodiments may also have applicability to display applications, organic photovoltaic cells and inorganic thin-film cells such as copper indium gallium selenide (GIGS); copper, zinc tin sulfide (CZTS); cadmium telluride, etc.

It will be apparent to those skilled in the art having regard to this disclosure that other modifications of the exemplary embodiments beyond those embodiments specifically described here may be made without departing from the spirit of the invention. Accordingly, such modifications are considered within the scope of the invention as limited solely by the appended claims.

What is claimed is:

1. A method comprising:
forming a bottom metallic electrode;
forming a semiconductor junction on the metallic electrode;
forming a transparent conducting overlayer in contact with the semiconductor junction; and
forming a metallic layer in contact with the transparent conducting overlayer, wherein the metallic layer is formed by a plating process.

2. The method of claim 1 wherein the metallic layer is interposed between the semiconductor junction and the transparent conducting overlayer so that the metallic layer makes direct contact with the semiconductor junction.

3. The method of claim 1 wherein the transparent conducting overlayer is interposed between the semiconductor junction and the metallic layer so that the transparent conducting overlayer makes direct contact with the semiconductor junction.

4. The method of claim 1 wherein the plating process is selected from the group consisting of electroplating and electroless plating.

5. The method of claim 1 wherein the metallic layer is a busbar having a plurality of fingers extending from a main portion of the busbar.

6. The method of claim 1 wherein the transparent conducting overlayer is selected from the group consisting of carbon nanotubes and graphene.

7. The method of claim 1 wherein the semiconductor junction is a p-i-n semiconductor junction or a p-n semiconductor junction having a p-type surface and an n-type surface with the n-type surface being in direct contact with the bottom metallic electrode.

8. The method of claim 1 wherein the semiconductor junction is an n-p semiconductor junction or an n-i-p semiconductor junction having a p-type surface and an n-type surface with the p-type surface being in direct contact with the bottom metallic electrode.

9. The method of claim 1 wherein a solar cell is produced by the method.

10. A method comprising:
forming a bottom metallic electrode;
forming a semiconductor junction on the metallic electrode , the semiconductor junction being in direct contact with the bottom metallic electrode;
forming a transparent conducting overlayer over and in direct contact with the semiconductor junction; and
forming a metallic layer over and in direct contact with the transparent conducting overlayer, wherein the metallic layer is formed by a plating process.

11. The method of claim 10 wherein the plating process is selected from the group consisting of electroplating and electroless plating.

12. The method of claim 10 wherein the metallic layer is a busbar having a plurality of fingers extending from a main portion of the busbar.

13. The method of claim 10 wherein the transparent conducting overlayer is selected from the group consisting of carbon nanotubes and graphene.

14. The method of claim 10 wherein a solar cell is produced by the method.

15. The method of claim 10 wherein the semiconductor junction is a p-i-n semiconductor junction, a p-n semiconductor junction, an n-p semiconductor junction or an n-i-p semiconductor junction.

16. The method of claim 15 wherein the semiconductor junction is a p-i-n semiconductor junction or a p-n semiconductor junction having a p-type surface and n-type surface and the p-type surface being in direct contact with the transparent conducting overlayer.

17. The method of claim 15 wherein the semiconductor junction is an n-p semiconductor junction or an n-i-p semiconductor junction having an n-type surface and a p-type surface and the n-type surface being in direct contact with the transparent conducting overlayer.

18. A method comprising:
forming a bottom metallic electrode;
forming a semiconductor junction on the metallic electrode , the semiconductor junction being in direct contact with the bottom metallic electrode;
forming a metallic layer over and in direct contact with the semiconductor junction, wherein the metallic layer is formed by a plating process; and
forming a transparent conducting overlayer over and in direct contact with the metallic layer.

19. The method of claim 18 wherein the plating process is selected from the group consisting of electroplating and electroless plating.

20. The method of claim 18 wherein the metallic layer is a busbar having a plurality of fingers extending from a main portion of the busbar.

21. The method of claim 18 wherein the transparent conducting overlayer is selected from the group consisting of carbon nanotubes and graphene.

22. The method of claim 18 wherein a solar cell is produced by the method.

23. The method of claim 18 wherein the semiconductor junction is a p-i-n semiconductor junction, a p-n semiconductor junction, an n-p semiconductor junction or an n-i-p semiconductor junction.

24. The method of claim 23 wherein the semiconductor junction is a p-i-n semiconductor junction or a p-n semiconductor junction having a p-type surface and n-type surface and the p-type surface being in direct contact with the metallic layer.

25. The method of claim 23 wherein the semiconductor junction is an n-p semiconductor junction or an n-i-p semiconductor junction having an n-type surface and a p-type surface and the n-type surface being in direct contact with the metallic layer.
